(19) United States
(12) Patent Application Publication
(10) Pub. No.: US 2026/0282988 A1
(43) Pub. Date: Sep. 17, 2026

(54) LASER PRINTING METHOD FOR MICROBUMPS IN PACKAGING THREE-DIMENSIONAL INTEGRATED CIRCUIT

(71) Applicant: SHANGHAI JIAO TONG UNIVERSITY, Shanghai (CN)

(72) Inventors: Yongxiang HU, Shanghai (CN); Zijie LU, Shanghai (CN); Guohu LUO, Shanghai (CN); Yishi ZHAO, Shanghai (CN); Di WU, Shanghai (CN)

(73) Assignee: SHANGHAI JIAO TONG UNIVERSITY, Shanghai (CN)

(21) Appl. No.: 19/678,322

(22) Filed: May 15, 2026

Related U.S. Application Data
(63) Continuation of application No. PCT/CN2024/124842, filed on Oct. 15, 2024.

(30) Foreign Application Priority Data
Nov. 16, 2023 (CN) 202311535220.X

(51) Int. Cl. H10W 72/00

(52) U.S. Cl. CPC H10W 72/01223; H10W 72/01204; H10W 72/01251

(57) ABSTRACT

The present invention provides a micro-bump laser printing method for three-dimensional integrated circuit packaging. The method comprises: placing a chiplet having pre-formed micro-pads on a chuck disclosed below a donor film; and irradiating the donor film in alignment using a pulsed laser such that the donor film locally molts and ejects metal droplets, wherein the metal droplets deposit on surfaces of the micro-pads, and cool to solidify, thereby forming an array of metal micro-bumps. The present invention forms micro-bumps by laser direct-write printing without using a mask, thereby achieving a simplified process flow and a short period. Micro-bump arrays having different sizes and positional distributions are formed by changing a size of a laser spot and irradiation positions on the donor film, thereby achieving high process flexibility. Micro-bumps having different compositions are formed by replacing a material of the donor film, thereby achieving a wide material applicability.

### CROSS-REFERENCE TO RELATED APPLICATIONS

This application is a continuation of International Patent Application No. PCT/CN2024/124842 filed on October 15, 2024, which claims priority to Chinese Patent Application No. 202311535220.X filed on November 16, 2023. The disclosures of the above-referenced applications are hereby incorporated by reference in their entirety.

### TECHNICAL FIELD

The present invention relates to the field of three-dimensional integrated circuit packaging technology, and in particular, to a micro-bump laser printing method for packaging a three-dimensional integrated circuit.

### BACKGROUND

Three-dimensional integrated circuits are high-density integrated circuits formed by stacking a plurality of two-dimensional integrated circuits, offering advantages such as low latency, high bandwidth, and compact size. Currently, as component density of three-dimensional integrated circuits continues to increase, micro-bumps—which serve as important components for electrical connections between chips in each layer—are also evolving toward higher density, finer pitch, and smaller volume, creating demand for high-resolution micro-bump fabrication methods. Furthermore, the three-dimensional heterogeneous integration of diverse chip types requires a highly process-flexible approach for fabricating micro-bumps of varying materials and dimensions.

Conventional micro-bump packaging methods for three-dimensional integrated circuits currently include mask electroplating, laser ball placement, droplet ejection, and the like.

Chinese Patent Application No. CN202111370657.3 discloses a method for fabricating micro-bumps using mask lithography and subsequent electroplating. The method first transfers a plurality of chips to be bumped onto a temporary bonding film, and then performs injection molding to reconstruct a wafer. After debonding from the temporary bonding film, lithography is employed to form a passivation layer on pads of the reconstructed chips, followed by sputtering a seed layer to form a conductive layer. A photoresist is then patterned to define electroplating openings, and micro-bumps of different sizes are deposited in a single electroplating step. Finally, the photoresist and seed layer are removed via a wet process, and a reflow step is performed to form micro-bumps of differing sizes for bonding to the chips. However, such a fabrication method is cumbersome and relatively costly. In addition, because micro-bumps occupy only a small fraction of the entire chip area, material utilization of the sputtered conductive layer is low. Furthermore, the method entails an extended process flow and slow throughput, rendering it difficult to implement flexible and diverse micro-bump patterning.

Chinese Patent Application No. CN201010222496.9 discloses a method for fabricating micro-bumps by laser ball placement. In this method, a nozzle picks up a micro-solder ball and places it at the center of a pad, and a laser then remelts the micro-solder ball to complete ball placement and bonding for a single pad. This process is mask-free and yields micro-bumps with favorable uniformity. Nevertheless, the step of picking up micro-solder ball adds processing time, resulting in low throughput. Furthermore, the micro-solder balls disclosed in this patent have a diameter ranging from 40 μm to 300 μm, which imposes limitations on further improving processing resolution.

Chinese Patent Application No. CN202211297440.9 discloses a printing device and method for a tin alloy bump array using a nozzle. Tin alloy is jetted through the nozzle onto a substrate to form bumps. local heating and melting of the tops of the bumps, coupled with adjustment of the initial oscillation height to reduce height errors, enable direct printing of highly coplanar thin alloy on a substrate at room temperature. Relative to electroplating processes, this approach adopts additive manufacturing, thereby simplifying the process low and eliminating contaminants such as waste liquids. However, nozzle-based printing suffers from low resolution and a high tendency for nozzle clogging.

Conventional processing techniques fail to simultaneously satisfy the requirements of high resolution, high processing efficiency, high material utilization, and high process flexibility for the fabrication of micro-bump arrays. Accordingly, there exists an urgent demand for a micro-bumps fabrication method for three-dimensional integrated circuit packaging that addresses the forgoing requirements.

### SUMMARY

To overcome the drawbacks of the prior art, an object of the present invention is to provide a micro-bump laser printing method for three-dimensional integrated circuit packaging.

According to the present invention, there is provided a micro-bump laser printing method for three-dimensional integrated circuit packaging comprising: placing a chiplet having pre-formed micro-pads on a chuck disposed below a donor film; and irradiating the donor film in alignment using a pulsed laser such that the donor film locally molts and ejects metal droplets, wherein the metal droplets deposit on surfaces of the micro-pads, and cool to solidify, thereby forming an array of metal micro-bumps.

Preferably, positions of the metal micro-bumps are determined by laser irradiation positions on the donor film, and patterned micro-bump arrays with different arrangements are fabricated by adjusting positions at which the laser beam irradiates the donor film.

Preferably, the micro-bump array is fabricated either by generating a patterned beam array having an arrangement identical to that of micro-bumps to be fabricated using a spatial light modulator, or by irradiating the donor film point-by-point via laser beam deflection controlled by a galvanometer scanner.

Preferably, sizes of the micro-bumps are adjusted by changing a size of a laser spot irradiating the donor film or a thickness of the donor film, to satisfy micro-bump fabrication requirements for packaging chiplets with different pad densities.

Preferably, a material composition of the micro-bumps is consistent with that of the donor film, and micro-bumps having different compositions are fabricated by replacing a material of the donor film.

Preferably, the chuck comprises a preheating assembly configured to preheat the micro-pads on a surface of the chiplet to a preset temperature, such that deposited metal droplets fully retract on surfaces of the micro-pads to form spherical micro-bumps.

Preferably, the micro-bump fabrication process is performed in a standard ambient environment, in a vacuum, or in an inert gas atmosphere.

In comparison with the prior art, the present invention affords the following advantageous effects:
1. Relative to micro-bump fabrication processes such as electroplating and ball placement, the present invention forms micro-bumps via an additive manufacturing process employing laser direct-write printing. The process is mask-free, and a single laser pulse completes the formation of a single micro-bump, thereby providing a simplified process flow, excellent material compatibility, and high processing resolution.
2. The present invention enables processing of micro-bumps of differing sizes by adjusting the profile of the patterned laser beam and the thickness of the donor film. The composition of the micro-bumps can be controlled by adjusting the composition of the donor film, rendering the process highly flexible.
3. By adjusting the positions at which the donor film is irradiated by the patterned laser beam, the present invention enables irradiated regions on the donor film to be arranged in a dense configuration via rational path planning—even when pads on the chiplet are dispersed—thereby improving utilization of the donor film.

### BRIEF DESCRIPTION OF THE DRAWINGS

Further features, objects, and advantages of the present invention will become more apparent upon reading the detailed description of non-limiting embodiments with reference to the accompanying drawings, in which:

FIG. 1 is a flow chart of a micro-bump laser printing method for three-dimensional integrated circuit packaging according to the present invention;

FIG. 2 is a schematic diagram illustrating alignment of laser irradiation positions on a donor film with micro-pad positions according to the present invention;

FIG. 3 is a schematic diagram illustrating laser printing of micro-bump arrays of different sizes, materials, and pitches according to the present invention;

FIG. 4 is a schematic diagram illustrating a three-dimensional integrated circuit packaging structure after laser printing of micro-bumps according to the present invention; and

FIG. 5 is a scanning electron microscope image showing the morphology of micro-bumps formed by laser printing according to the present invention.

### Reference Numerals

1 micro-pad

1-1 first batch of micro-pads

1-2 second batch of micro-pads

1-3 third batch of micro-pads

2 chiplet

2-1 first chiplet

2-2 second chiplet

2-3 third chiplet

5 patterned pulsed laser beam

6 transparent donor substrate

7 donor film

8-1 first batch of micro-bumps

8-2 second batch of micro-bumps

8-3 third batch of micro-bumps

9 chuck

10 interposer

### DETAILED DESCRIPTION

The present invention is described in detail below in conjunction with specific embodiments. The following embodiments will assist those skilled in the art in further understanding the present invention, but are not intended to limit the scope of the present invention in any manner. It should be noted that, for a person of ordinary skill in the art, several modifications and improvements may be made without departing from the concepts of the present invention, and such modifications and improvements are all within the scope of the present invention.

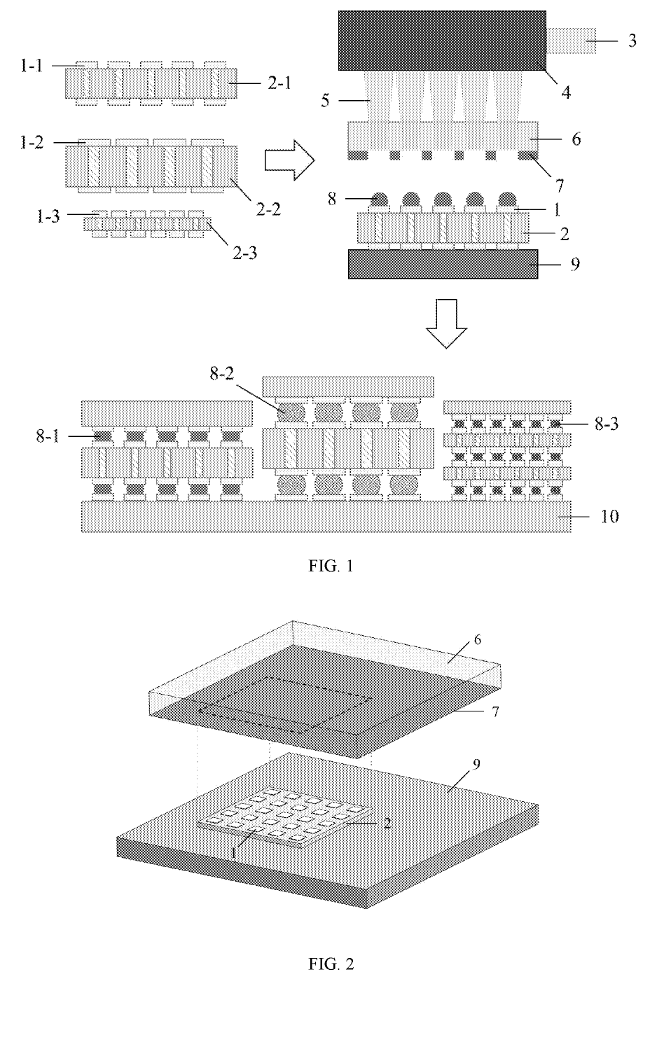

The present invention discloses a micro-bump laser printing method for three-dimensional integrated circuit packaging. Referring to FIG. 1, a chiplet 2 having pre-formed micro-pads 1 is placed on a chuck 9 disposed below a donor film 7. A focused pulsed laser 5 irradiates the donor film 7 in alignment above the micro-pads 1, thereby inducing localized melting of the donor film 7 and ejection of metal droplets. The ejected metal droplets deposit onto the surfaces of the micro-pads 1 directly therebelow and cool to solidify, thereby forming metal micro-bumps. Based on the material, size, and arrangement of micro-bumps required for packaging the chiplet 2, as well as the positions of the micro-pads 1, the material of the donor film 7, the laser spot size, and the irradiation positions on the donor film 7 are selected to rapidly form metal micro-bumps. The micro-bumps electrically interconnect different chiplets 2 to achieve three-dimensional integrated circuit packaging.

In the above scheme, the positions at which micro-bumps are formed are determined by the laser irradiation positions on the donor film 7. Patterned micro-bump arrays having different arrangements may be formed by adjusting the positions at which the laser beam irradiates the donor film 7. The patterned micro-bump arrays may be formed by generating a patterned beam array having an arrangement matching that of the micro-bumps to be formed using a spatial light modulator, or by irradiating the donor film 7 point-by-point via laser beam deflection controlled by a galvanometer scanner. The size of the formed micro-bumps is adjusted by changing the size of the laser spot irradiating the donor film 7 or the thickness of the donor film 7, to satisfy micro-bumps formation requirements for packaging chiplets 2 having different pad densities. The material composition of the micro-bumps is consistent with that of the donor film 7, and micro-bumps having different compositions are formed by replacing the material of the donor film 7. The chuck 9 carrying the chiplet 2 has a preheating function configured to heat the micro-pads 1 on the surface of the chiplet 2 to a predetermined temperature, such that the deposited metal droplets fully retract on the surfaces of the micro-pads 1 to form spherical micro-bumps. Anti-oxidation measures may be adopted during micro-bumps formation, including vacuum evacuation or provision of an inert gas environment.

The present invention is described in further detail below in conjunction with a specific example.

The present invention enables laser printing formation and packaging of micro-bumps for three-dimensional integrated circuits, and exhibits advantages of high resolution, high process flexibility, high material utilization, and high processing efficiency, thereby meeting the three-dimensional packaging requirements of the semiconductor industry.

Referring to FIGS. 2 through 5, the present embodiment is a micro-bump laser printing method for three-dimensional integrated circuit packaging, comprising the following steps:

Step S1: Select an appropriate donor film 7, a preheating temperature for the chuck 9, parameters for the patterned pulsed laser beam 5, and anti-oxidation measures based on the material and size of micro-bumps 8-1 to be formed on a first chiplet 2-1;

Step S2: Align irradiation positions of the patterned pulsed laser beam 5 with the first batch of micro-pads 1-1 corresponding to the micro-bumps 8-1 to be fabricated, as shown in FIG. 2. Subsequently, as shown in FIG. 2, the laser beam emits a pulse that passes through a transparent donor substrate 6 to transfer the irradiated material of the donor film 7 onto the first batch of micro-pads 1-1 therebelow, where the material cools to form the first batch of micro-bumps 8-1;

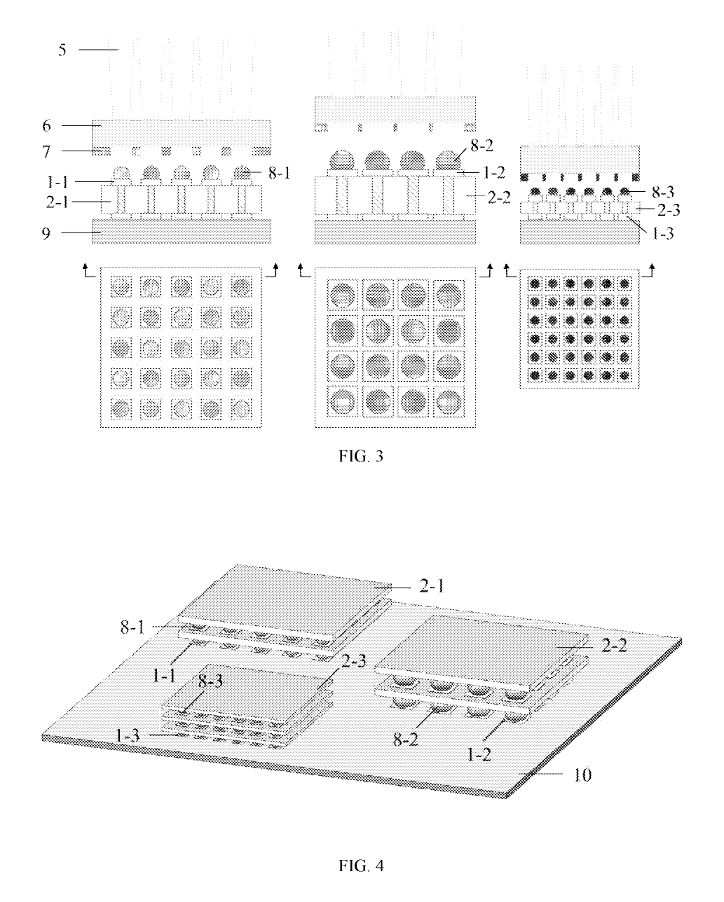

Step S3: Repeat Steps S1 to S2 to form remaining micro-bump arrays 8-2 and 8-3 having different sizes, materials, or pitches, as shown in FIG. 3. During this process, adjust the relative positions of the patterned pulsed laser beam 5, the donor film 7, the second batch of micro-pads 1-2, and the third batch of micro-pads 1-3 to densely arrange the irradiated regions on the donor film 7, thereby improving material utilization;

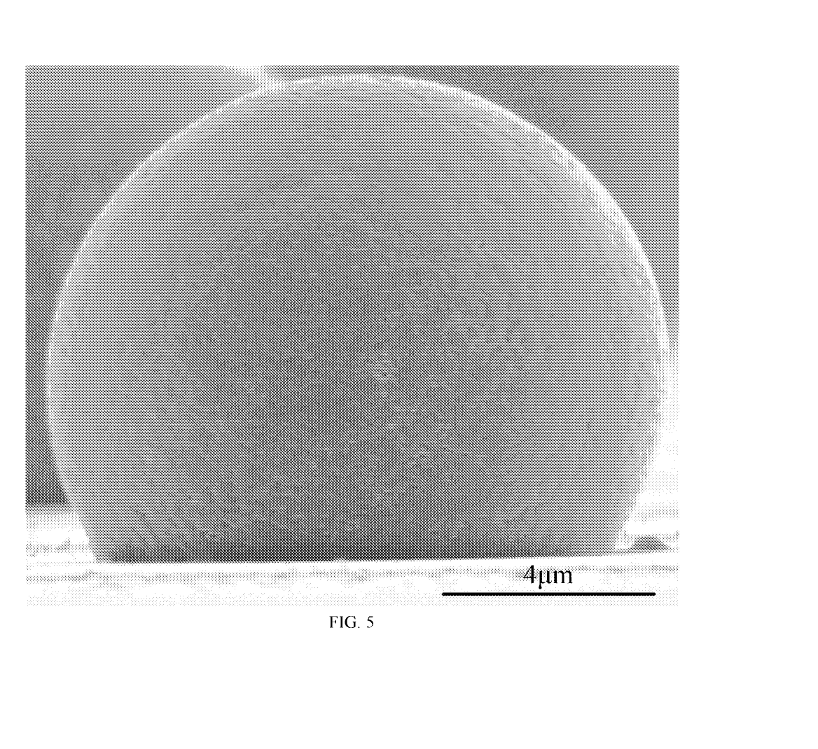

Step S4: After completing formation of each batch of micro-bumps 8-1, 8-2, and 8-3, sequentially stack the first chiplet 2-1, the second chiplet 2-2, and the third chiplet 2-3 onto an interposer 10 to achieve three-dimensional integrated circuit packaging, as shown in FIG. 4.

The morphology of the formed micro-bumps under a scanning electron microscope is shown in FIG. 5, and the micro-bumps exhibit favorable roundness.

The present invention forms micro-bumps for three-dimensional integrated circuit packaging by laser direct-write printing. It aims to achieve mass production of micro-bumps for three-dimensional integrated circuits while balancing high resolution, high process flexibility, high material utilization, and high processing speed, thereby facilitating efficient three-dimensional integrated circuit packaging.

In the description of the present application, it should be understood that orientation or positional relationships indicated by terms such as “upper,” “lower,” “front,” “back,” “left,” “right,” “vertical,” “horizontal,” “top,” “bottom,” “inside,” “outside,” and the like are based on those shown in the accompanying drawings. These are provided solely for the purpose of facilitating the description of the present application and simplifying the description, and are not intended to indicate or imply that the devices or elements referred to must have a specific orientation, be constructed in a specific orientation, or operate in a specific orientation. Therefore, they should not be construed as limitations on the present application.

The above describes specific embodiments of the present invention. It should be understood that the present invention is not limited to the specific embodiments described above. Those skilled in the art may make various changes or modifications within the scope of the appended claims without departing from the spirit and scope of the present invention. The embodiments of the present application and features thereof may be arbitrarily combined with one another without conflict.

What is claimed is:

1. A micro-bump laser printing method for three-dimensional integrated circuit packaging, characterized in that, the method comprises: placing a chiplet having pre-formed micro-pads on a chuck disposed below a donor film; and
irradiate the donor film in alignment using a pulsed laser such that the donor film locally molts and ejects metal droplets, wherein the metal droplets deposit on surfaces of the micro-pads and cool to solidify, thereby forming an array of metal micro-bumps.

2. The micro-bump laser printing method for three-dimensional integrated circuit packaging according to claim 1, wherein positions of the metal micro-bumps are determined by laser irradiation positions on the donor film, and patterned micro-bump arrays having different arrangements are formed by adjusting positions at which a laser beam irradiates the donor film.

3. The micro-bump laser printing method for three-dimensional integrated circuit packaging according to claim 1, wherein the micro-bump array is formed either by generating a patterned beam array having an arrangement identical to that of micro-bumps to be formed using a spatial light modulator, or by irradiating the donor film point-by-point via laser beam deflection controlled by a galvanometer scanner.

4. The micro-bump laser printing method for three-dimensional integrated circuit packaging according to claim 1, wherein sizes of the micro-bumps are adjusted by changing a size of a laser spot irradiating the donor film or a thickness of the donor film, to satisfy micro-bumps formation requirements for packaging chiplets having different pad densities.

5. The micro-bump laser printing method for three-dimensional integrated circuit packaging according to claim 1, wherein a material composition of the micro-bumps is consistent with that of the donor film, and micro-bumps having different compositions are formed by replacing a material of the donor film.

6. The micro-bump laser printing method for three-dimensional integrated circuit packaging according to claim 1, wherein the chuck comprises a preheating assembly configured to preheat the micro-pads on a surface of the chiplet to a preset temperature, such that deposited metal droplets fully retract on surfaces of the micro-pads to form spherical micro-bumps.

7. The micro-bump laser printing method for three-dimensional integrated circuit packaging according to claim 1, wherein the micro-bump formation process is performed in a normal ambient environment, in a vacuum, or in an inert gas atmosphere.
